(19) United States
(12) Patent Application Publication
(10) Pub. No.: US 2022/0411258 A1
(43) Pub. Date: Dec. 29, 2022

(54) DISTANCE MEASUREMENT APPARATUS, ANGLE-OF-VIEW CONTROL METHOD, AND COMPUTER-READABLE RECORDING MEDIUM STORING PROGRAM

(71) Applicant: FUJITSU LIMITED, Kawasaki-shi (JP)

(72) Inventors: Koichi Iida, Kobe (JP); Arata EJIRI, Machida (JP); KOSUKE YANAI, Kawasaki (JP); Shinichi Fujiyoshi, Fukuoka (JP); Koichi Tezuka, Shibuya (JP); Takeshi MORIKAWA, Yokohama (JP); Katsushi Sakai, Zama (JP)

(73) Assignee: FUJITSU LIMITED, Kawasaki-shi (JP)

(21) Appl. No.: 17/896,257

(22) Filed: Aug. 26, 2022

Related U.S. Application Data
(63) Continuation of application No. PCT/JP2020/016111, filed on Apr. 10, 2020.

(51) Int. Cl. B81B 7/00; G01S 17/42; G01S 7/481

(52) U.S. Cl. CPC B81B 7/0003; G01S 17/42; G01S 7/4817

(57) ABSTRACT

A scanning-type distance measurement apparatus that includes a two-dimensional micro electro mechanical system (MEMS) mirror that reflects a laser beam includes: a memory; and a processor coupled to the memory and configured to: drive, on an axis that controls an angle of view out of two axes orthogonal to each other of the two-dimensional MEMS mirror, the axis of the two-dimensional MEMS mirror with a drive signal; and control a scanning angle range of the laser beam when a drive waveform of the drive signal is offset by an offset amount to shift a center angle of the scanning angle range, on the basis of the offset amount according to a shift direction from the center angle.

### CROSS-REFERENCE TO RELATED APPLICATION

This application is a continuation application of International Application PCT/JP2020/016111 filed on Apr. 10, 2020 and designated the U.S., the entire contents of which are incorporated herein by reference.

### FIELD

The embodiments discussed herein are related to a distance measurement apparatus, an angle-of-view control method, and a program.

### BACKGROUND

A scanning-type distance measurement apparatus using a laser beam is also referred to as a laser radar, a laser sensor, or the like. The scanning-type distance measurement apparatus reflects a laser beam by, for example, a two-dimensional micro electro mechanical system (MEMS) mirror and two-dimensionally scans a measurement object so that a distance to the measurement object may be measured.

Japanese Laid-open Patent Publication No. 2018-155784 and Japanese Laid-open Patent Publication No. 2018-054752 are disclosed as related art.

### SUMMARY

According to an aspect of the embodiments, a scanning-type distance measurement apparatus that includes a two-dimensional micro electro mechanical system (MEMS) mirror that reflects a laser beam includes: a memory; and a processor coupled to the memory and configured to: drive, on an axis that controls an angle of view out of two axes orthogonal to each other of the two-dimensional MEMS mirror, the axis of the two-dimensional MEMS mirror with a drive signal; and control a scanning angle range of the laser beam when a drive waveform of the drive signal is offset by an offset amount to shift a center angle of the scanning angle range, on the basis of the offset amount according to a shift direction from the center angle.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a distance measurement apparatus in a first embodiment;

FIG. 2 is a block diagram illustrating an example of a computer;

FIG. 3 is a diagram illustrating an example of a housing of the distance measurement apparatus;

FIG. 4 is a diagram illustrating an example of a drive signal having a resonance drive waveform;

FIG. 5 is a diagram illustrating an example of a drive signal having a non-resonance drive waveform;

FIG. 6 is a flowchart for describing an example of distance measurement processing;

FIG. 7 is a functional block diagram illustrating an example of an angle-of-view control unit in the first embodiment;

FIG. 8 is a diagram for describing an example of a relationship between a shift angle and an offset amount;

FIG. 9 is a flowchart for describing an example of processing of the angle-of-view control unit in the first embodiment;

FIG. 10 is a diagram illustrating an example of a shift angle offset table;

FIG. 11 is a diagram illustrating an example of an offset correction table;

FIG. 12 is a functional block diagram illustrating an example of an angle-of-view control unit in a second embodiment;

FIG. 13 is a diagram illustrating an example of a first shift angle offset table;

FIG. 14 is a diagram illustrating an example of a second shift angle offset table;

FIG. 15 is a diagram illustrating an example of an offset correction table;

FIG. 16 is a flowchart for describing an example of processing of the angle-of-view control unit in the second embodiment; and

FIG. 17 is a diagram for describing an angle-of-view switching section.

### DESCRIPTION OF EMBODIMENTS

The scanning-type distance measurement apparatus may be applied to sensing of a person, an object, a space, or the like, and in the case of such an application, it is desirable to perform sensing in real time and with high resolution. Furthermore, the scanning-type distance measurement apparatus may also be applied to generation of three-dimensional data and a distance image with no occlusion by, for example, simultaneously measuring an exercising person from a plurality of directions. The three-dimensional data and the distance images may be used for, for example, scoring artistic gymnastics.

It is desirable that a scanning speed of a laser beam by the two-dimensional MEMS mirror is high and an angle of view of the scanning by the laser beam is large. On the other hand, in order to perform sensing of a measurement object with high resolution, it is conceivable to increase a laser emission repetition speed. However, this measure has limitations. Thus, a technology has been proposed in which an angle of view is reduced and a center angle of a scanning angle range by a laser beam is shifted to follow a measurement object.

Moreover, a technology has also been proposed in which, in order to expand a scanning angle range by a laser beam while maintaining measurement resolution, an angle of view is dynamically controlled according to movement of a measurement object to change the scanning angle range.

The two-dimensional MEMS mirror may control a center shift amount of a scanning angle range by changing magnitude of a scanning angle width and an offset amount by changing amplitude of a voltage of a drive signal to be driven, and may change the scanning angle range, for example, an angle of view. However, in a case where a center angle of a scanning angle range is deviated when the center angle is shifted, accuracy of setting the scanning angle range of a laser beam by the two-dimensional MEMS mirror deteriorates.

With the known scanning-type distance measurement apparatus including the two-dimensional MEMS mirror, it is difficult to accurately shift a center angle of a scanning angle range by a laser beam.

Thus, in one aspect, an object is to provide a distance measurement apparatus, an angle-of-view control method, and a program capable of accurately shifting a center angle of a scanning angle range by a laser beam in a scanning-type distance measurement apparatus including a two-dimensional MEMS mirror.

In a disclosed distance measurement apparatus, angle-of-view control method and program, a two-dimensional micro electro mechanical system (MEMS) mirror for reflecting a laser beam is driven by a drive signal having a sinusoidal wave drive waveform using resonance on one axis out of two axes orthogonal to each other of the two-dimensional MEMS mirror, and a sawtooth waveform on the other axis on a non-resonance drive side that controls an angle of view. Hereinafter, the non-resonance side will be described unless otherwise specified. In dynamic control of an angle of view for shifting a center angle of a scanning angle range of a laser beam by offsetting a drive waveform of a drive signal by an offset amount, the offset amount is changed according to a shift direction from the center angle, and the scanning angle range is controlled so that the shift angle matches regardless of the shift direction.

Hereinafter, each embodiment of the disclosed distance measurement apparatus, angle-of-view control method, and program will be described with reference to the drawings.

### Embodiments

A technology has been proposed in which, in order to expand a scanning angle range by a laser beam while maintaining measurement resolution, an angle of view is dynamically controlled according to movement of a measurement object to change the scanning angle range in a scanning-type distance measurement apparatus including a two-dimensional micro electro mechanical system (MEMS) mirror. The scanning angle range may be changed by changing an offset amount of a voltage of a drive signal that drives the two-dimensional MEMS mirror. However, it has been found that even when the offset amount for shifting a center angle of the scanning angle range is the same, the center angle of the scanning angle range may be deviated depending on a shift direction.

The present inventors have found that, in the case of a two-dimensional MEMS mirror driven by a piezoelectric element, since the piezoelectric element has a hysteresis characteristic, a phenomenon that a center angle of a scanning angle range is deviated according to a shift direction occurs even when an offset amount for shifting the center angle is the same. When the center angle of the scanning angle range is deviated according to the shift direction, scanning accuracy of a laser beam by the two-dimensional MEMS mirror deteriorates. For example, the present inventors have found that, in a scanning-type distance measurement apparatus including a two-dimensional MEMS mirror driven by a driving element having a hysteresis characteristic, it is difficult to accurately shift a center angle of a scanning angle range by a laser beam regardless of a shift direction.

Thus, in view of the phenomenon described above, a distance measurement apparatus, an angle-of-view control method, and a program in each embodiment described below have a configuration in which a center angle of a scanning angle range of a laser beam by a two-dimensional MEMS mirror is accurately shifted regardless of a shift direction of the center angle of the scanning angle range.

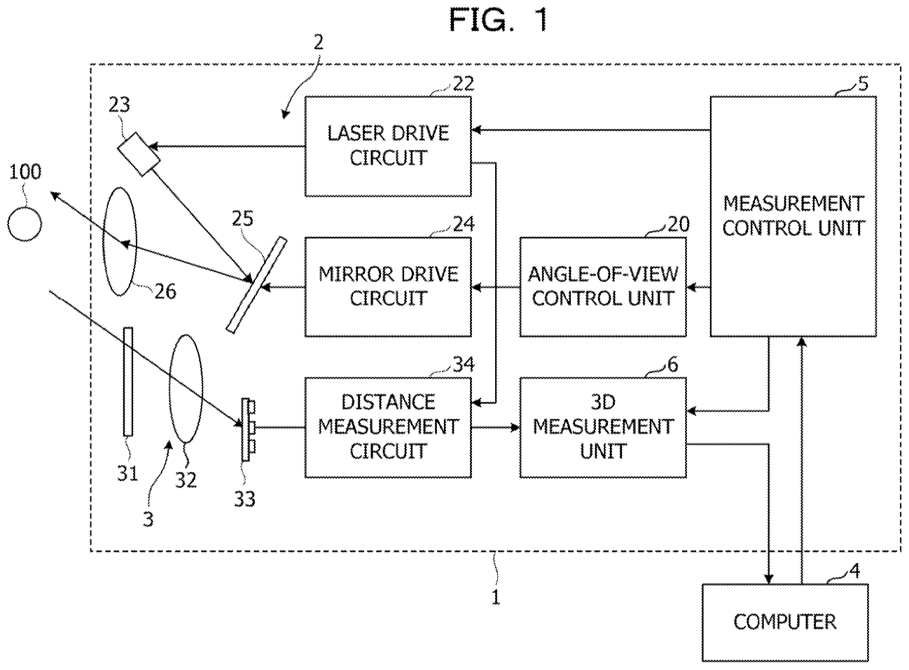

FIG. 1 is a diagram illustrating an example of a distance measurement apparatus in a first embodiment. The scanning-type distance measurement apparatus illustrated in FIG. 1 includes an apparatus main body 1 and a computer 4. The apparatus main body 1 includes a light projection unit 2, a light reception unit 3, a measurement control unit 5, and a three-dimensional (3D) measurement unit 6.

When starting distance measurement processing, the computer 4 supplies setting data including a sampling interval (or sampling density) and an azimuth angle to a measurement object 100 and the like to the measurement control unit 5 of the apparatus main body 1. The azimuth angle to the measurement object 100 will be described later.

The light projection unit 2 includes an angle-of-view control unit 20, a laser drive circuit 22, a laser diode 23, a two-axis mirror drive circuit 24, a two-dimensional MEMS mirror 25, and an angle expansion lens 26. The laser diode 23 is an example of a laser light source. The two-dimensional MEMS mirror 25 is an example of a two-axis scanning mirror. The angle expansion lens 26 is an example of a light projection lens.

The measurement control unit 5 generates an emission timing signal indicating an emission timing of the laser diode 23 on the basis of the sampling interval included in the setting data from the computer 4, and supplies the light emission timing signal to the laser drive circuit 22. The laser drive circuit 22 drives the laser diode 23 to emit light at the emission timing indicated by the emission timing signal.

Furthermore, the measurement control unit 5 generates an angle-of-view change instruction and an angle-of-view parameter on the basis of the azimuth angle to the measurement object 100 and the like included in the setting data from the computer 4. Initial values of a scanning angle range (or angle of view), a center angle of the scanning angle range, and the like before the start of the distance measurement processing or before dynamic control of the angle of view may be supplied from the computer 4 to the measurement control unit 5 together with the setting data, or may be set in advance in the measurement control unit 5. The measurement control unit 5 generates the angle-of-view change instruction in a case where it is determined that the angle of view is dynamically changed from the initial value (for example, 0 degrees) of the center angle of the scanning angle range and the azimuth angle to the measurement object 100 included in the setting data. The angle-of-view change instruction includes a shift angle (or shift amount) and a shift direction of the center angle of the scanning angle range. The angle-of-view parameter includes the scanning angle range and the center angle of the scanning angle range. The measurement control unit 5 supplies the generated angle-of-view parameter to the angle-of-view control unit 20. The computer 4 may have the function of generating the angle-of-view change instruction of the measurement control unit 5 described above.

The angle-of-view control unit 20 changes the angle-of-view parameter including the scanning angle range and the center angle of the scanning angle range in response to the angle-of-view change instruction output by the measurement control unit 5, and supplies the angle-of-view parameter to the mirror drive circuit 24. For example, the angle-of-view control unit 20 changes the angle-of-view parameter according to the shift angle and the shift direction in the angle-of-view change instruction, and supplies a drive control signal for driving the two-dimensional MEMS mirror 25 on two axes to the mirror drive circuit 24.

The mirror drive circuit 24 outputs a drive signal for driving the two-dimensional MEMS mirror 25 on two axes according to the drive control signal and a correction offset amount described later, and a well-known drive unit (not illustrated) drives and displaces the two-dimensional MEMS mirror 25 on two axes on the basis of the drive signal. In this example, the drive unit is a piezoelectric element included in the two-dimensional MEMS mirror 25. A two-dimensional MEMS mirror itself which is driven on two axes and incorporating a piezoelectric element is well known (see, for example, Japanese Laid-open Patent Publication No. 2018-155784), and such a well-known two-dimensional MEMS mirror may be used for the two-dimensional MEMS mirror 25. Note that the drive unit may be a separate body from the two-dimensional MEMS mirror 25.

In this example, the measurement control unit 5 has a function of controlling a drive timing of the laser diode 23 by the laser drive circuit 22, a drive timing of the two-dimensional MEMS mirror 25 by the mirror drive circuit 24 via the angle-of-view control unit 20, and a distance measurement timing by the apparatus main body 1.

The mirror drive circuit 24 is an example of a drive unit. The drive unit drives the two-dimensional MEMS mirror 25 by the drive signal having a sinusoidal wave drive waveform using resonance on one axis out of two axes orthogonal to each other of the two-dimensional MEMS mirror 25 and a sawtooth waveform on the other axis on a non-resonance drive side that controls an angle of view. On the axis that controls the angle of view, the drive unit drives the axis of the two-dimensional MEMS mirror 25 with the drive signal. The angle-of-view control unit 20 is an example of a control unit. When the drive waveform of the drive signal is offset by an offset amount to shift a center angle of a scanning angle range of a laser beam, the drive unit controls the scanning angle range on the basis of the offset amount according to a shift direction.

A laser beam emitted from the laser diode 23 is reflected (or deflected) by the two-dimensional MEMS mirror 25, and performs scanning of a scanning angle range through the angle expansion lens 26, which is, for example, raster scanning. By such raster scanning, the laser beam (or laser pulse) scans the scanning angle range at a position a certain distance away from the apparatus main body 1. The position a certain distance away from the apparatus main body 1 is, for example, a position of the measurement object 100. The scanning angle range has a width corresponding to a distance in which the laser beam moves from one end to the other end of the scanning angle range substantially parallel to a horizontal plane (or a ground surface), for example, at the position a certain distance away from the apparatus main body 1. Furthermore, the scanning angle range is equal to an angle of view of scanning by the laser beam, and refers to an angle at which the laser beam scans in a horizontal direction and an angle at which the laser beam scans in a vertical direction regardless of the distance from the apparatus main body 1. Note that, for convenience of description, it is assumed that the angle of view of scanning by the laser beam may be dynamically controlled on a non-resonance drive side of the two-dimensional MEMS mirror 25 in the vertical direction, and is fixed on a resonance drive side in the horizontal direction.

The light reception unit 3 includes a filter 31, a condenser lens 32, a light reception element 33, and a distance measurement circuit 34. Reflected light from the measurement object 100 is detected by the light reception element 33 through the filter 31 and the condenser lens 32. The filter 31 is an example of a band-pass filter (BPF) that allows only a laser beam in a target wavelength band used by the distance measurement apparatus to pass through, and has a well-known configuration. The condenser lens 32 is an example of a light reception lens. The light reception element 33 is an example of a photodetector that supplies a light reception signal representing the detected reflected light to the distance measurement circuit 34. The distance measurement circuit 34 measures a time of flight (TOF) ΔT from when a laser beam is emitted from the light projection unit 2 until when the laser beam is reflected by the measurement object 100 and returns to the light reception unit 3. Note that the timing at which the light projection unit 2 emits the laser beam is notified from the laser drive circuit 22 to the distance measurement circuit 34 according to the drive timing of the laser diode 23 by the laser drive circuit 22. With this configuration, the distance measurement circuit 34 optically measures a distance to the measurement object 100, and supplies distance data indicating the measured distance to the 3D measurement unit 6. Here, when a light speed is represented by c (about 300,000 km/s), the distance to the measurement object 100 may be obtained from (c×ΔT)/2, for example.

The 3D measurement unit 6 generates a distance image and three-dimensional (3D) data on the basis of mirror angle data stored in a mirror emission angle table included in the measurement control unit 5 and the distance data from the distance measurement circuit 34. The mirror emission angle table indicates a relationship of a mirror angle of the two-dimensional MEMS mirror 25 at the time of laser emission at each sampling point. For example, the 3D measurement unit 6 generates the distance image from the distance data, and generates the 3D data from the distance image and the mirror angle data indicating the mirror angle. The distance image is an image in which distance values at respective ranging points are arranged in the order of samples subjected to raster scanning. Furthermore, the 3D measurement unit 6 generates light projection angle data indicating a light projection angle of a laser beam for each sample from the mirror angle data, or may have the light projection angle data as a table. The 3D data may be generated by converting the distance image by using the distance value and the light projection angle data, and includes information regarding the distance to the measurement object 100 and the light projection angle of the laser beam for each sample.

The distance image and the 3D data are supplied to the computer 4, and the computer 4 may perform, for example, processing of extracting the measurement object 100 and processing of calculating the azimuth angle to the measurement object 100 on the basis of the distance image and the 3D data. A method of extracting the measurement object 100 from the distance image is not particularly limited. For example, when the measurement object 100 is a person, the measurement object 100 may be extracted by detecting a shape such as a posture that the person may take from the distance image by a well-known method. Furthermore, the azimuth angle to the measurement object 100 may be calculated by a well-known method from the extracted measurement object 100 and information regarding a light projection angle of the 3D data.

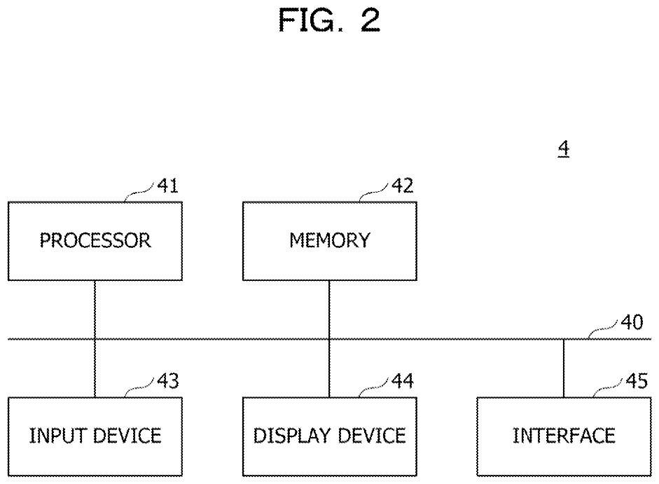

FIG. 2 is a block diagram illustrating an example of the computer. The computer 4 illustrated in FIG. 2 includes a processor 41, a memory 42, an input device 43, a display device 44, and an interface (or communication device) 45 that are connected to each other via a bus 40. The processor 41 may be formed by, for example, a central processing unit (CPU), and executes a program stored in the memory 42 to control the entire computer 4. The memory 42 may be formed by a computer-readable storage medium. The computer-readable storage medium includes, for example, a non-transitory computer-readable storage medium such as a semiconductor storage device, a magnetic recording medium, an optical recording medium, or a magneto-optical recording medium. The memory 42 stores various programs including a distance measurement program to be executed by the processor 41, various types of data, various tables, and the like.

The input device 43 may be formed by, for example, a keyboard operated by a user (or operator), and is used to input commands, data, and the like to the processor 41. The display device 44 is used to display a message to a user, a measurement result of the distance measurement processing, and the like. The interface 45 communicably connects the computer 4 with another computer and the like. In this example, the computer 4 is connected to the measurement control unit 5 via the interface 45.

Note that the computer 4 is not limited to have the hardware configuration in which the components of the computer 4 are connected via the bus 40. Furthermore, as the computer 4, for example, a personal computer (PC) or a general-purpose computer may be used.

The input device 43 and the display device 44 of the computer 4 may be externally connected, and may be omitted. Furthermore, in the case of a module, a semiconductor chip, or the like in which the interface 45 of the computer 4 is omitted, an output of the apparatus main body 1 (for example, an output of the measurement control unit 5) may be connected to the bus 40 or may be directly connected to the processor 41.

For example, a semiconductor chip or the like incorporating the computer 4 may be provided in the apparatus main body 1. In this case, the computer 4 may include at least a part of the functions of, for example, the measurement control unit 5, the angle-of-view control unit 20, and the 3D measurement unit 6. In a case where the computer 4 (for example, the processor 41 and the memory 42) includes the function of the angle-of-view control unit 20, the computer 4 may form the control unit described above.

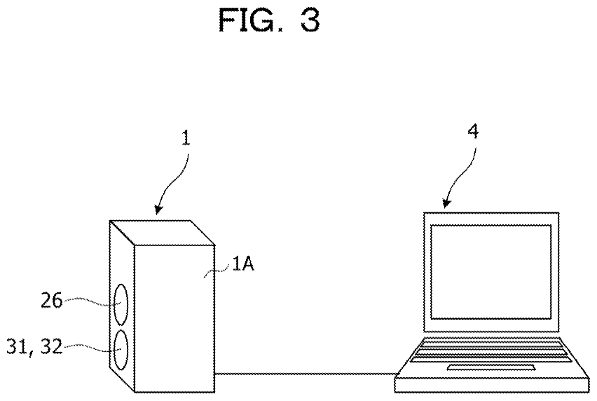

FIG. 3 is a diagram illustrating an example of a housing of the distance measurement apparatus. In FIG. 3, for convenience of description, an example is illustrated in which the apparatus main body 1 of the distance measurement apparatus is connected to the computer 4. The apparatus main body 1 includes a housing 1A, and the light projection unit 2, the light reception unit 3, the measurement control unit 5, the 3D measurement unit 6, and the like are housed in the housing 1A. In this example, the angle expansion lens 26 of the light projection unit 2 and the filter 31 and the condenser lens 32 of the light reception unit 3 are arranged on a side of one side surface of the housing 1A.

Note that the computer 4 may be a separate body from the distance measurement apparatus. In this case, the distance measurement apparatus may include only the apparatus main body 1, and the computer 4 may be formed by, for example, a cloud computing system.

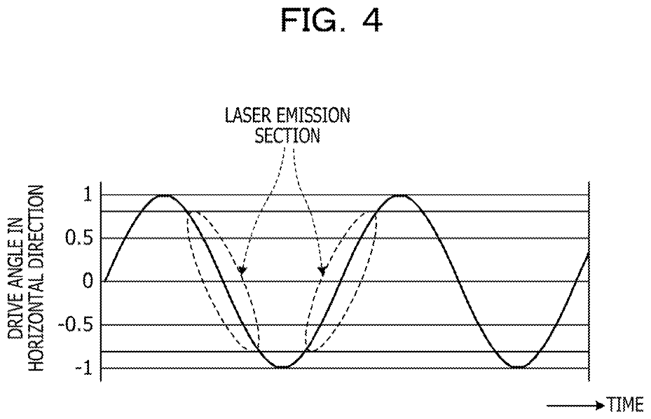

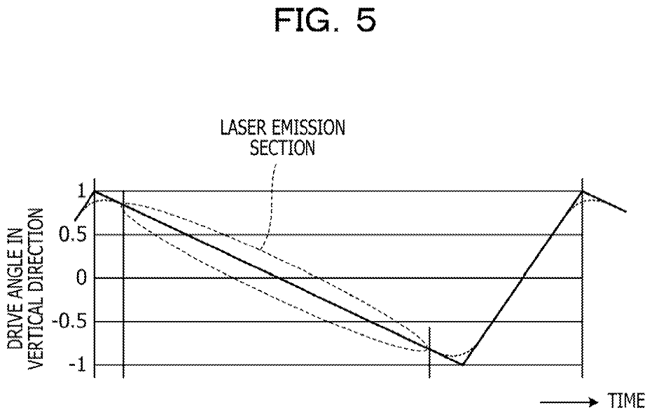

In the present embodiment, a drive signal having a sinusoidal wave (for example, a drive voltage), which is an example of a non-linear resonance drive waveform illustrated in FIG. 4, is used for driving the two-dimensional MEMS mirror 25 in the horizontal direction. In FIG. 4, a vertical axis indicates a drive angle in the horizontal direction in an optional unit, and a horizontal axis indicates a time in an optional unit. Furthermore, a drive signal having a sawtooth wave (for example, a drive voltage), which is an example of a linear non-resonance drive waveform illustrated in FIG. 5, is used for driving the two-dimensional MEMS mirror 25 in the vertical direction orthogonal to the horizontal direction. In FIG. 5, a vertical axis indicates a drive angle in the vertical direction in an optional unit, and a horizontal axis indicates a time in an optional unit. In FIGS. 4 and 5, a broken line indicates a laser emission section which is an emission section of the laser diode 23. The angle-of-view control unit 20 has a function of offsetting a drive signal having a non-resonance drive waveform output by the mirror drive circuit 24 by an offset amount to shift a center angle of a scanning angle range of a laser beam. Furthermore, the angle-of-view control unit 20 has a function of controlling the scanning angle range so that a shift angle matches regardless of a shift direction by changing (or correcting) and determining the offset amount according to the shift direction when shifting the center angle. For example, the angle-of-view control unit 20 has a function of controlling the scanning angle range on the basis of the offset amount according to the shift direction from the center angle when shifting the center angle.

Note that the drive signal having the non-resonance drive waveform may be used for driving the two-dimensional MEMS mirror 25 in the horizontal direction, and the drive signal having the resonance drive waveform may be used for driving the two-dimensional MEMS mirror 25 in the vertical direction. Furthermore, the distance measurement apparatus may have an arrangement inclined at an optional angle relative to the horizontal plane, for example.

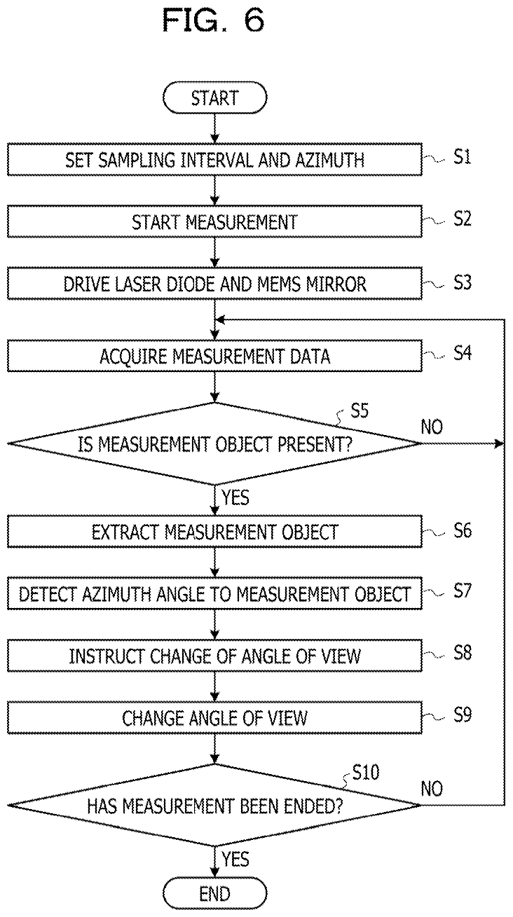

FIG. 6 is a flowchart for describing an example of the distance measurement processing. The distance measurement processing is started by, for example, the processor 41 of the computer 4 executing the distance measurement program stored in the memory 42.

In FIG. 6, for example, when the distance measurement processing is started in response to a command input from the input device 43, in Step S1, the computer 4 sets setting data including a sampling interval and an azimuth angle to the measurement object 100 and the like in the measurement control unit 5 of the apparatus main body 1.

In Step S2, the computer 4 causes the measurement control unit 5 of the apparatus main body 1 to start measurement of a distance at a distance measurement timing according to the setting data.

In Step S3, the computer 4 causes the measurement control unit 5 of the apparatus main body 1 to drive the laser diode 23 via the laser drive circuit 22 at a drive timing according to the setting data. Furthermore, in Step S3, the computer 4 causes the measurement control unit 5 of the apparatus main body 1 to drive a piezoelectric element of the two-dimensional MEMS mirror 25 via the angle-of-view control unit 20 and the mirror drive circuit 24 at the drive timing according to the setting data.

In Step S4, the computer 4 acquires measurement data including a distance image, 3D data, and the like from the 3D measurement unit 6 of the apparatus main body 1. In Step S5, the computer 4 determines whether or not the measurement object 100 is present on the basis of the 3D data and the distance image of the measurement data, and the processing returns to Step S4 when the determination result is No while the processing proceeds to Step S6 when the determination result is Yes. It is possible to determine whether or not the measurement object 100 is present within a scanning angle range subjected to raster scanning by a well-known method. For example, when the measurement object 100 is a person, the presence of the measurement object 100 may be determined by detecting a shape of a posture of the person, a skin color of the face of the person, and the like from the distance image. Furthermore, a method in which the generated 3D data or distance image is displayed on the display device 44 of the computer 4, and in a case where a user specifies (clicks) a desired position or range of a display screen with the input device 43 such as a mouse, it is determined that the measurement object 100 is present, or the like may be adopted.

In Step S6, since the measurement object 100 is present within the scanning angle range subjected to the raster scanning, the computer 4 extracts the measurement object 100 detected from the distance image by a well-known method, for example, and obtains object data of the extracted measurement object 100. In Step S7, the computer 4 calculates an azimuth angle to the measurement object 100 from, for example, the extracted object data and information regarding a light projection angle of the 3D data by a well-known method, and stores the azimuth angle in the memory 42 as needed.

In Step S8, the measurement control unit 5 of the apparatus main body 1 calculates a setting value of each of the scanning angle range, a center angle of the scanning angle range, and a shift angle so as to be the azimuth angle to the measurement object 100 included in the setting data from the computer 4. In Step S8, the measurement control unit 5 of the apparatus main body 1 outputs an angle-of-view change instruction and the setting value of each of the scanning angle range, the center angle of the scanning angle range, and the shift angle to the angle-of-view control unit 20, and instructs change of an angle of view when the angle of view is dynamically controlled.

In Step S9, the angle-of-view control unit 20 of the apparatus main body 1 changes the angle of view according to the angle-of-view change instruction from the measurement control unit 5. For example, the angle-of-view control unit 20 outputs a correction offset amount described later to the mirror drive circuit 24 together with a drive control signal to drive the two-dimensional MEMS mirror 25. The details of the angle-of-view change processing in Steps S8 and S9 will be described later.

Note that the angle-of-view change processing in Steps S8 and S9 may be started by, for example, a processor forming the measurement control unit 5 and the angle-of-view control unit 20 executing an angle-of-view change program stored in the memory. Furthermore, in a case where the computer 4 includes the functions of the measurement control unit 5 and the angle-of-view control unit 20, it is sufficient that the computer 4 executes the angle-of-view change processing in Steps S8 and S9.

In Step S10, the computer 4 determines whether or not the distance measurement processing has been ended, and the processing returns to Step S4 when the determination result is No while the processing ends when the determination result is Yes.

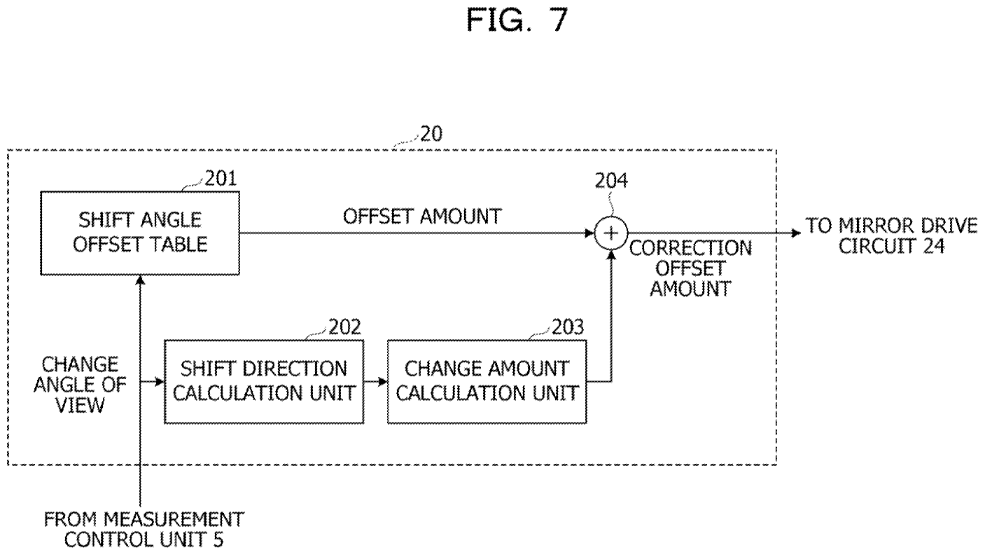

FIG. 7 is a functional block diagram illustrating an example of the angle-of-view control unit in the first embodiment. As illustrated in FIG. 7, the angle-of-view control unit 20 includes a shift angle offset table 201, a shift direction calculation unit 202, a change amount calculation unit 203, and an addition unit 204. In an example in which a shift direction from bottom to top is used as a reference according to a hysteresis characteristic of a piezoelectric element of the two-dimensional MEMS mirror 25, an offset amount is corrected only in the case of a shift direction from top to bottom.

The angle-of-view control unit 20 calculates an offset amount with respect to a shift angle according to a shift direction with reference to the shift angle offset table 201 on the basis of an angle-of-view change instruction from the measurement control unit 5, and supplies the offset amount to the addition unit 204. The shift direction calculation unit 202 calculates the shift direction on the basis of the angle-of-view change instruction. When the shift direction (in this example, from top to bottom) needs change of the offset amount, the change amount calculation unit 203 refers to an offset correction table. The change amount calculation unit 203 calculates a change amount (offset correction amount) with respect to a shift angle difference according to the shift direction for changing (or correcting) the offset amount from the offset correction table, and supplies the change amount (offset correction amount) to the addition unit 204. The shift angle difference indicates an angle difference between center angles of a scanning angle range before and after the shift. The offset correction table is provided in, for example, the change amount calculation unit 203. On the other hand, when the shift direction (in this example, from bottom to top) does not need change of the offset amount, the change amount calculation unit 203 does not refer to the offset correction table and does not output the change amount (or outputs the change amount of zero (0)). The addition unit 204 outputs the offset amount in a case where the change amount is not supplied from the change amount calculation unit 203, and outputs the offset amount obtained by adding the change amount as a correction offset amount in a case where the change amount is supplied from the change amount calculation unit 203.

Therefore, the angle-of-view control unit 20 outputs the correction offset amount from the addition unit 204 to the mirror drive circuit 24 together with a drive control signal to drive the two-dimensional MEMS mirror 25. For example, the angle-of-view control unit 20 causes the mirror drive circuit 24 to output a drive signal having a non-resonance drive waveform for driving the two-dimensional MEMS mirror 25 in the vertical direction. In this example, the mirror drive circuit 24 includes an adjustment circuit that generates a drive signal having a sawtooth waveform subjected to voltage adjustment or the like on the basis of the correction offset amount and the drive control signal from the angle-of-view control unit 20. However, such an adjustment circuit may be separately provided between the angle-of-view control unit 20 and the mirror drive circuit 24.

Note that, although the angle-of-view control unit 20 causes the mirror drive circuit 24 to output a drive signal having a resonance drive waveform for driving the two-dimensional MEMS mirror 25 in the horizontal direction, driving by such a drive signal itself is well known, and description thereof is omitted.

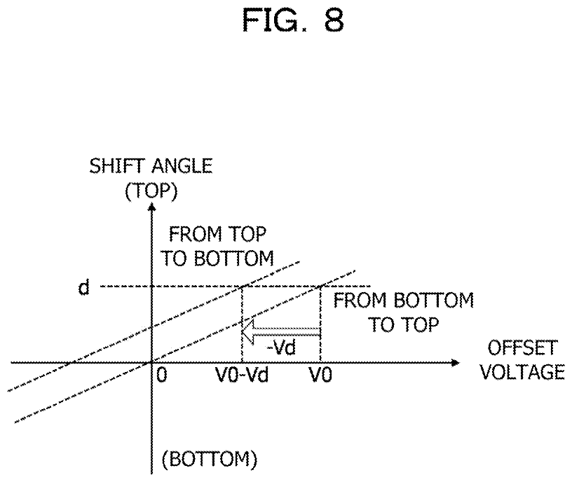

FIG. 8 is a diagram for describing an example of a relationship between a shift angle and an offset amount. In FIG. 8, a vertical axis indicates a shift angle of a center angle of a scanning angle range in an optional unit, and a horizontal axis indicates an offset voltage corresponding to an offset amount for offsetting a drive signal having a resonance drive waveform in an optional unit. FIG. 8 is an example in which a shift direction from bottom to top is used as a reference according to a hysteresis characteristic of a piezoelectric element of the two-dimensional MEMS mirror 25 and the offset amount is corrected only in the case of a shift direction from top to bottom.

In a case where a deviation angle assumed when the shift angle is changed is d degrees, an angle-of-view parameter is changed according to the following procedure. First, in a case where the deviation angle when the center angle of the scanning angle range is shifted in an upward direction is d degrees, an offset voltage corresponding to an offset amount for shifting the center angle in the upward direction by d degrees is added to the drive signal having the resonance drive waveform. Similarly, in a case where the deviation angle when the center angle of the scanning angle range is shifted in a downward direction is d degrees, an offset voltage corresponding to an offset amount for shifting the center angle in the downward direction by d degrees is subtracted from the drive signal having the resonance drive waveform.

However, in this example, since the shift direction from bottom to top is used as a reference according to the hysteresis characteristic of the piezoelectric element of the two-dimensional MEMS mirror 25, only in the case of the shift direction from top to bottom, the offset voltage corresponding to the offset amount is changed. In the example illustrated in FIG. 8, the offset voltage in a case where the shift angle is set to d degrees in the case of the shift direction from bottom to top used as a reference is a reference voltage V0. On the other hand, the offset voltage in a case where the shift angle is set to d degrees in the case of the shift direction from top to bottom is changed to V0−Vd by adding a voltage −Vd corresponding to a change amount (offset correction amount). As a result, the center angle of the scanning angle range may be accurately shifted regardless of the shift direction of the center angle of the scanning angle range.

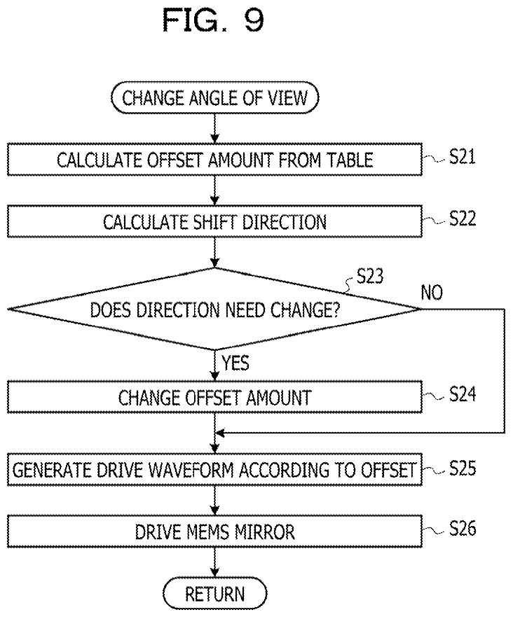

FIG. 9 is a flowchart for describing an example of the processing of the angle-of-view control unit in the first embodiment. FIG. 9 is an example in which a shift direction from bottom to top is used as a reference according to a piezoelectric element and an offset amount is corrected only in the case of a shift direction from top to bottom. The angle-of-view change processing indicated in FIG. 9 corresponds to the processing of Steps S8 and S9 in the distance measurement processing indicated in FIG. 6.

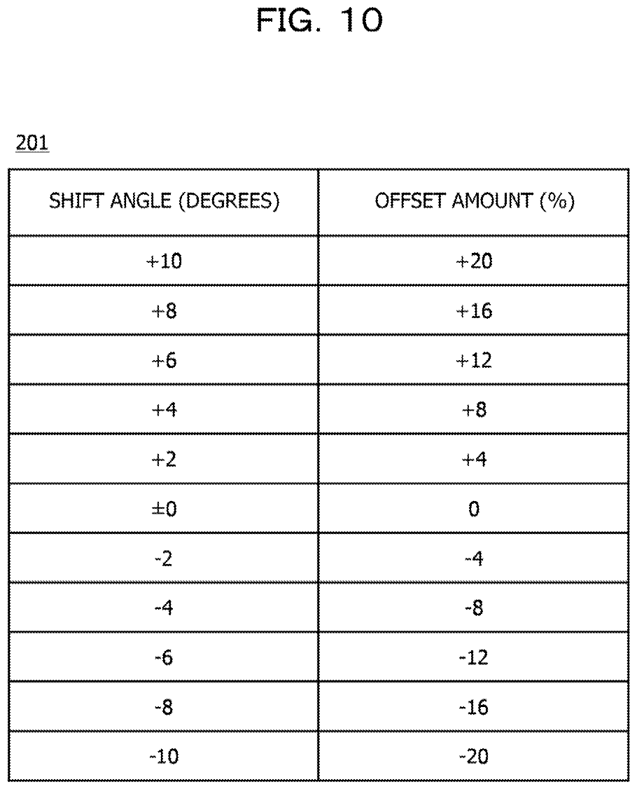

The angle-of-view control unit 20 starts the angle-of-view change processing in response to an angle-of-view change instruction from the measurement control unit 5. In Step S21, the angle-of-view control unit 20 calculates an offset amount with respect to a shift angle according to a shift direction with reference to, for example, the shift angle offset table 201 illustrated in FIG. 10 on the basis of the angle-of-view change instruction, and supplies the offset amount to the addition unit 204. In Step S22, the shift direction calculation unit 202 calculates the shift direction on the basis of the angle-of-view change instruction. In Step S23, the change amount calculation unit 203 determines whether or not the shift direction (in this example, from top to bottom) needs change of the offset amount. When the determination result in Step S23 is No, the processing proceeds to Step S25 described later.

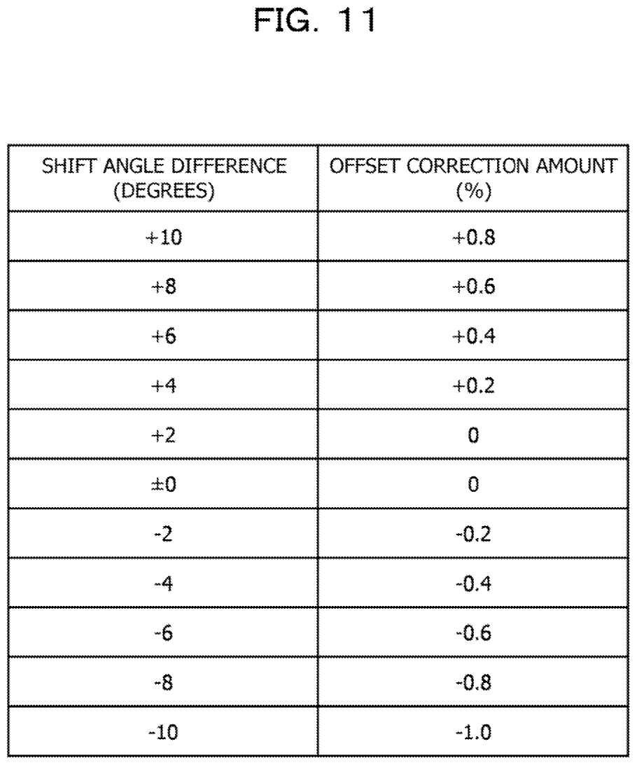

When the determination result in Step S23 is Yes, in Step S24, the change amount calculation unit 203 supplies the offset amount (constant) corresponding to FIG. 8 depending on the direction to the addition unit 204. In Step S25, the addition unit 204 outputs the offset amount in a case where a change amount is not supplied from the change amount calculation unit 203, and outputs the offset amount obtained by adding the change amount as a correction offset amount in a case where the change amount is supplied from the change amount calculation unit 203. Here, in a case where a shift amount may also be calculated in addition to the direction in the shift direction calculation unit 202, the change amount calculation unit 203 calculates a change amount (offset correction amount) with respect to a shift angle difference according to the shift direction with reference to an offset correction table illustrated in FIG. 11 and supplies the change amount (offset correction amount) to the addition unit 204.

In Step S26, the angle-of-view control unit 20 outputs the correction offset amount to the mirror drive circuit 24 together with a drive control signal to drive the two-dimensional MEMS mirror 25. For example, the angle-of-view control unit 20 causes the mirror drive circuit 24 to output a drive signal having a non-resonance drive waveform for driving the two-dimensional MEMS mirror 25 in the vertical direction. After Step S26, the processing returns to Step S10 of the distance measurement processing indicated in FIG. 6.

Note that the processing of Steps S23 and S24 may be executed before the processing of Steps S21 and S22. Furthermore, the processing of Steps S21 and S22 and the processing of Steps S23 and S24 may be executed in parallel.

FIG. 10 is a diagram illustrating an example of the shift angle offset table. The shift angle offset table 201 illustrated in FIG. 10 stores an offset amount (%) used as an output with respect to a shift angle (degrees) according to a shift direction used as an input. The shift angle (degrees) indicated in FIG. 10 indicates a shift angle from a state where a center angle of a scanning angle range is zero (0) degrees by a positive (+) value in the case of a shift direction from bottom to top and by a negative (−) value in the case of a shift direction from top to bottom. Furthermore, the offset amount (%) is a value obtained by dividing an offset voltage corresponding to the offset amount by the maximum amplitude of a drive voltage having a non-resonance drive waveform.

Note that, there may be a case where the shift angle according to a matching shift direction is not stored in the shift angle offset table 201 of FIG. 10 when the angle-of-view control unit 20 calculates the offset amount with respect to the shift angle according to the shift direction. In this case, the offset amount with respect to the shift angle according to the shift direction may be calculated by a well-known method such as approximation from the offset amount with respect to the stored shift angle according to the shift direction.

FIG. 11 is a diagram illustrating an example of the offset correction table. The offset correction table illustrated in FIG. 11 stores an offset correction amount (%) used as an output with respect to a shift angle difference (degrees) according to a shift direction used as an input. The shift angle difference (degrees) indicated in FIG. 11 indicates an angle difference between center angles of a scanning angle range before and after the shift by a positive (+) value in the case of a shift direction from bottom to top and by a negative (−) value in the case of a shift direction from top to bottom. Furthermore, the offset correction amount (%) is a value obtained by dividing an offset correction voltage corresponding to the offset correction amount by the maximum amplitude of a drive voltage having a non-resonance drive waveform.

Note that, there may be a case where a matching shift angle difference is not stored in the offset correction table of FIG. 11 when the change amount calculation unit 203 calculates the offset correction amount with respect to the shift angle difference according to the shift direction. In this case, the offset correction amount with respect to the shift angle difference according to the shift direction may be calculated by a well-known method such as approximation from the offset correction amount with respect to the stored shift angle difference according to the shift direction.

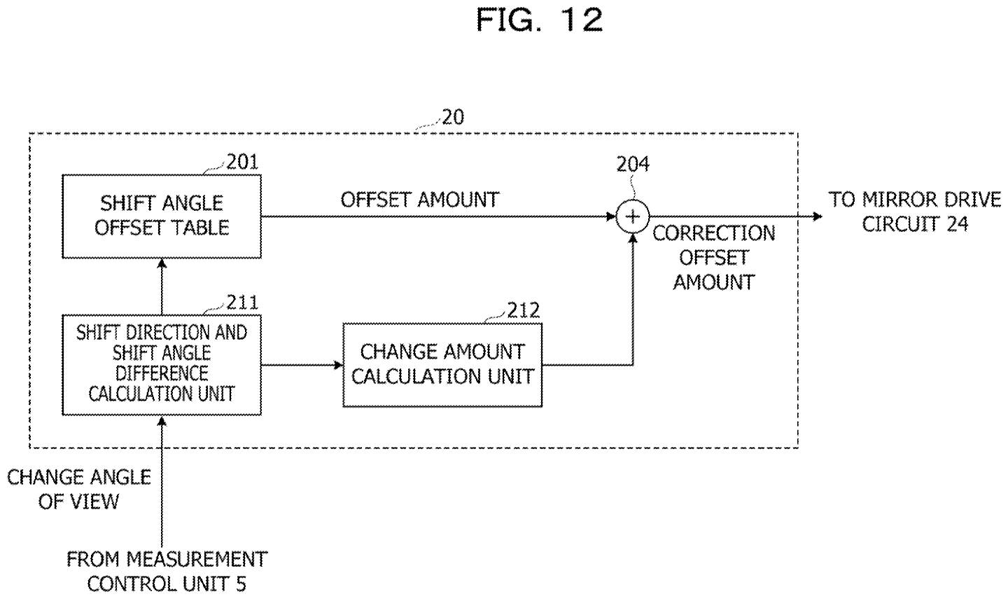

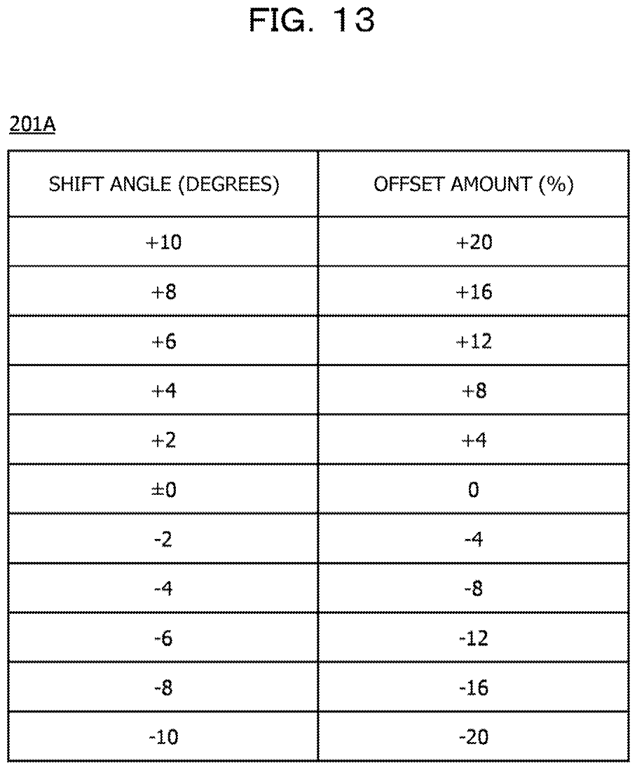

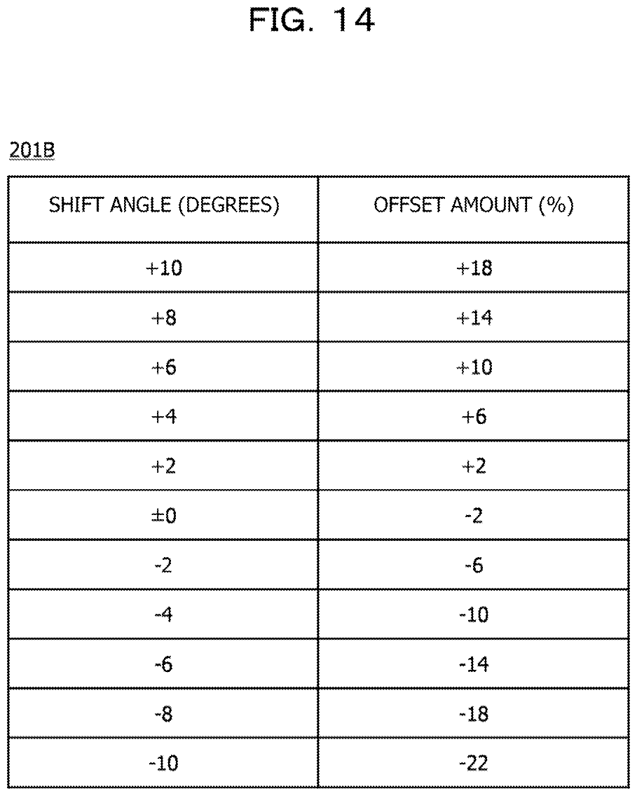

FIG. 12 is a functional block diagram illustrating an example of an angle-of-view control unit in a second embodiment. As illustrated in FIG. 12, an angle-of-view control unit 20 includes a shift angle offset table 201, a shift direction and shift angle difference calculation unit 211, a change amount calculation unit 212, and an addition unit 204. In this example, the shift angle offset table 201 includes a first shift angle offset table 201A illustrated in FIG. 13 and a second shift angle offset table 201B illustrated in FIG. 14.

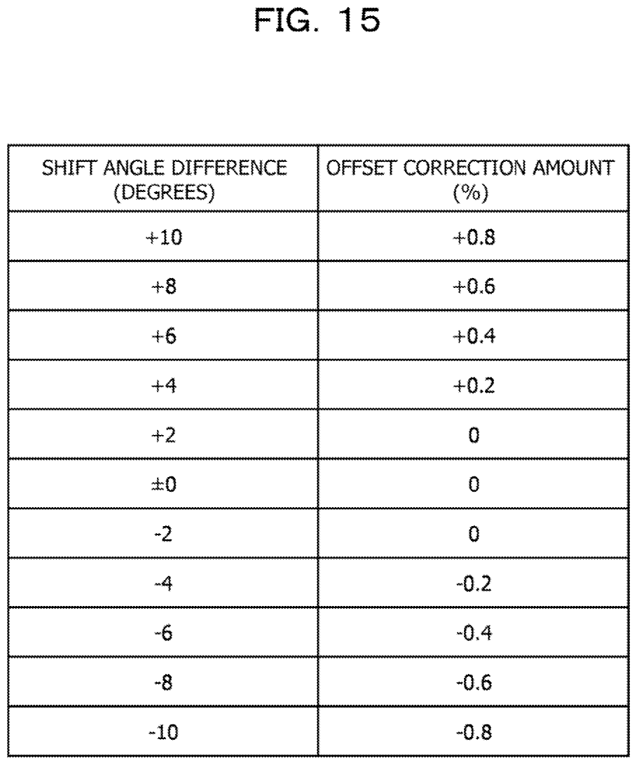

In FIG. 12, the shift direction and shift angle difference calculation unit 211 of the angle-of-view control unit 20 calculates a shift direction and a shift angle difference on the basis of an angle-of-view change instruction from a measurement control unit 5. The angle-of-view control unit 20 calculates an offset amount with respect to a shift angle according to the calculated shift direction with reference to the shift angle offset table 201, and supplies the offset amount to the addition unit 204. At this time, the angle-of-view control unit 20 selects and refers to the shift angle offset table 201A or the shift angle offset table 201B according to the calculated shift direction. For example, the angle-of-view control unit 20 selects and refers to the first shift angle offset table 201A in the case of a shift direction from bottom to top, and selects and refers to the second shift angle offset table 201B in the case of a shift direction from top to bottom. Furthermore, the shift direction and shift angle difference calculation unit 211 supplies the calculated shift direction and shift angle difference to the change amount calculation unit 212. The shift angle difference indicates an angle difference between center angles of a scanning angle range before and after the shift. The change amount calculation unit 212 calculates an offset correction amount with respect to the shift angle difference according to the calculated shift direction with reference to an offset correction table illustrated in FIG. 15, for example, and supplies the offset correction amount to the addition unit 204. The addition unit 204 outputs the offset amount in a case where a change amount (offset correction amount) is not supplied from the change amount calculation unit 212, and outputs the offset amount obtained by adding the change amount as a correction offset amount in a case where the change amount is supplied from the change amount calculation unit 212.

The shift angle offset tables 201A and 201B illustrated in FIGS. 13 and 14 store an offset amount (%) used as an output with respect to a shift angle (degrees) according to a shift direction used as an input. The shift angle (degrees) indicated in FIGS. 13 and 14 indicates a shift angle from a state where a center angle of a scanning angle range is zero (0) degrees by a positive (+) value in the case of a shift direction from bottom to top and by a negative (−) value in the case of a shift direction from top to bottom. For example, the shift direction from bottom to top is an example of a first shift direction, and the shift direction from top to bottom is an example of a second shift direction, which is an opposite direction to the first shift direction. Furthermore, the offset amount (%) is a value obtained by dividing an offset voltage corresponding to the offset amount by the maximum amplitude of a drive voltage having a non-resonance drive waveform. By making it possible to select the shift angle offset tables 201A and 201B according to the shift direction, it is possible to obtain a more accurate offset amount according to characteristics of the individual piezoelectric elements according to the shift direction.

Note that, there may be a case where a matching shift angle is not stored in the shift angle offset table 201A or 201B of FIG. 13 or FIG. 14 when the angle-of-view control unit 20 calculates the offset correction amount with respect to the shift angle according to the shift direction. In this case, the offset amount with respect to the shift angle according to the shift direction may be calculated by a well-known method such as approximation from the offset amount with respect to the stored shift angle according to the shift direction.

FIG. 15 is a diagram illustrating an example of the offset correction table. The offset correction table illustrated in FIG. 15 stores an offset correction amount (%) used as an output with respect to a shift direction and a shift angle difference (degrees) used as an input. The shift angle difference (degrees) indicated in FIG. 15 indicates an angle difference between center angles of a scanning angle range before and after the shift by a positive (+) value in the case of a shift direction from bottom to top and by a negative (−) value in the case of a shift direction from top to bottom. Furthermore, the offset correction amount (%) is a value obtained by dividing an offset correction voltage corresponding to the offset correction amount by the maximum amplitude of a drive voltage having a non-resonance drive waveform.

Note that, there may be a case where a matching shift angle difference is not stored in the offset correction table of FIG. 15 when the change amount calculation unit 212 calculates the offset correction amount with respect to the shift angle difference according to the shift direction. In this case, the offset correction amount with respect to the shift angle difference according to the shift direction may be calculated by a well-known method such as approximation from the offset correction amount with respect to the stored shift angle difference according to the shift direction.

Therefore, the angle-of-view control unit 20 outputs the correction offset amount from the addition unit 204 to a mirror drive circuit 24 together with a drive control signal to drive a two-dimensional MEMS mirror 25. For example, the angle-of-view control unit 20 causes the mirror drive circuit 24 to output a drive signal having a non-resonance drive waveform for driving the two-dimensional MEMS mirror 25 in the vertical direction. In this example, the mirror drive circuit 24 includes an adjustment circuit that generates a drive signal having a sawtooth waveform subjected to voltage adjustment or the like on the basis of the correction offset amount and the drive control signal from the angle-of-view control unit 20. However, such an adjustment circuit may be separately provided between the angle-of-view control unit 20 and the mirror drive circuit 24.

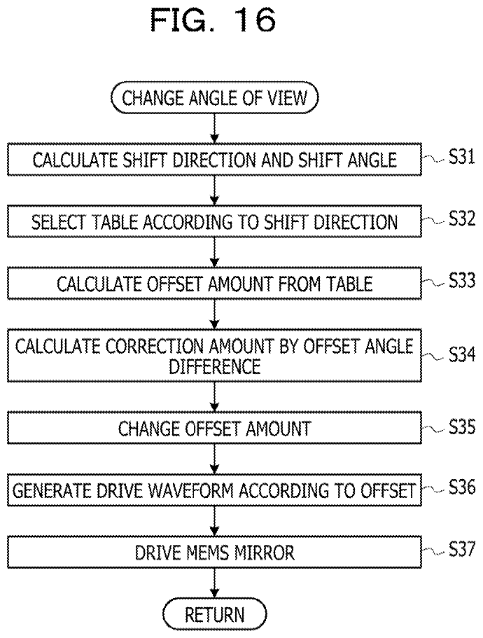

FIG. 16 is a flowchart for describing an example of processing of the angle-of-view control unit in the second embodiment. In this example, in the case of a shift direction from bottom to top, an offset amount is calculated by using the first shift angle offset table 201A illustrated in FIG. 13. Furthermore, in the case of a shift direction from top to bottom, an offset amount is calculated by using the second shift angle offset table 201B illustrated in FIG. 14. For example, in this example, the offset amount is different between the case of the shift direction from bottom to top and the case of the shift direction from top to bottom. Angle-of-view change processing indicated in FIG. 16 corresponds to the processing of Steps S8 and S9 in the distance measurement processing indicated in FIG. 6.

The angle-of-view control unit 20 starts the angle-of-view change processing in response to an angle-of-view change instruction from the measurement control unit 5. In Step S31, the shift direction and shift angle difference calculation unit 211 calculates a shift direction and a shift angle on the basis of the angle-of-view change instruction, and supplies the shift direction and the shift angle to the change amount calculation unit 212. In Step S32, the angle-of-view control unit 20 selects the first shift angle offset table 201A illustrated in FIG. 13 or the second shift angle offset table 201B illustrated in FIG. 14 according to the calculated shift direction. For example, the first shift angle offset table 201A is selected in the case of the shift direction from bottom to top, and the second shift angle offset table 201B is selected in the case of the shift direction from top to bottom. In Step S33, the angle-of-view control unit 20 calculates an offset amount with respect to a shift angle according to the calculated shift direction with reference to the selected shift angle offset table 201A or 201B, and supplies the offset amount to the addition unit 204. In Step S34, the change amount calculation unit 212 refers to, for example, the offset correction table illustrated in FIG. 15. For example, the change amount calculation unit 212 calculates a change amount (offset correction amount) with respect to a shift angle difference according to the calculated shift direction for changing the offset amount with reference to the offset correction table.

In Step S35, the change amount calculation unit 212 supplies the calculated change amount to the addition unit 204. In Step S36, the addition unit 204 outputs the offset amount in a case where the change amount is not supplied from the change amount calculation unit 212, and outputs the offset amount obtained by adding the change amount as a correction offset amount in a case where the change amount is supplied from the change amount calculation unit 212. In Step S37, the angle-of-view control unit 20 outputs the correction offset amount to the mirror drive circuit 24 together with a drive control signal to drive a two-dimensional MEMS mirror 25. For example, the angle-of-view control unit 20 causes the mirror drive circuit 24 to output a drive signal having a non-resonance drive waveform for driving the two-dimensional MEMS mirror 25 in the vertical direction. After Step S37, the processing returns to Step S10 of the distance measurement processing indicated in FIG. 6.

Note that the processing of Steps S34 and S35 may be executed before the processing of Steps S32 and S33. Furthermore, the processing of Steps S32 and S33 and the processing of Steps S34 and S35 may be executed in parallel.

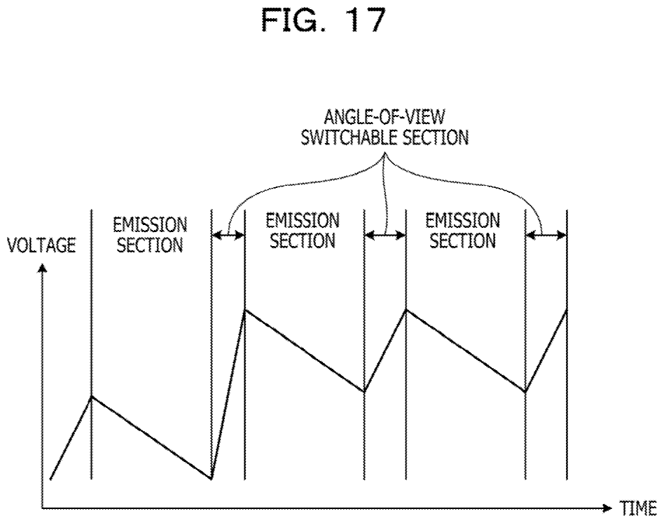

FIG. 17 is a diagram for describing an angle-of-view switching section. In FIG. 17, a vertical axis indicates a voltage of a drive signal having a non-resonance drive waveform in an optional unit, and a horizontal axis indicates a time in an optional unit. In this example, the angle-of-view switching section for controlling an angle of view is a folding section between folding of a non-resonance drive waveform of a drive signal after end of emission of a laser beam and before start of emission of the laser light. The angle-of-view control unit 20 changes an offset amount in the angle-of-view switching section excluding an emission section of the laser diode 23. Therefore, in both the first and second embodiments described above, the angle-of-view control unit 20 outputs the correction offset amount from the addition unit 204 to the mirror drive circuit 24 in the angle-of-view switching section described above. For example, the measurement control unit 5 supplies the angle-of-view change instruction and the angle-of-view parameter to the angle-of-view control unit 20 on the basis of the sampling interval included in the setting data from the computer 4, and causes the mirror drive circuit 24 to output the correction offset amount from the addition unit 204 in the angle-of-view switching section described above. With this configuration, the center angle of the scanning angle range by the laser beam may be shifted in the angle-of-view switching section other than the emission section of the laser diode 23, and the shift does not adversely affect measurement accuracy of the distance measurement apparatus.

In each of the embodiments described above, the two-dimensional MEMS mirror 25 has a piezoelectric element driven by a drive signal having a non-resonance drive waveform along one axis for controlling an angle of view to control the angle of view of scanning by a laser beam. However, the drive unit of the two-dimensional MEMS mirror 25 is not limited to the piezoelectric element, and may be, for example, a driving element other than the piezoelectric element, having a similar hysteresis characteristics to that of the piezoelectric element.

According to each of the embodiments described above, in the scanning-type distance measurement apparatus including the two-dimensional MEMS mirror, it is possible to accurately shift a center angle of a scanning angle range by a laser beam.

The distance measurement apparatus may be applied to a scoring assistance system, an in-vehicle system, or the like. An example of the scoring assistance system assists, for example, scoring of a gymnastics performance on the basis of an output of the distance measurement apparatus. In this case, the measurement object 100 is a gymnast, and the scoring may be performed by the computer 4 illustrated in FIG. 2 executing a scoring program, for example. It is sufficient that the computer 4 acquires skeleton information of the gymnast by a well-known method on the basis of 3D data and a distance image from the 3D measurement unit 6. Since the skeleton information of the gymnast includes a three-dimensional position of each joint of the gymnast in each frame, it is possible to recognize elements of a gymnastics performance from the skeleton information to score the gymnastics performance from a degree of completion of the elements.

Since a moving speed of the gymnast is high in the case of the gymnastics performance, an angle of view of the distance measurement apparatus needs to be controlled according to a position of the gymnast. According to each of the embodiments described above, even when a center angle of a scanning angle range is shifted in the vertical direction according to movement of the gymnast, the center angle may be controlled equally regardless of a shift direction, so that the position and size of the gymnast in the vertical direction are not changed. As a result, it is possible to suppress deterioration in the measurement accuracy of the distance measurement apparatus even when the moving speed of the gymnast is high, and by using an output of such a distance measurement apparatus, it is possible to perform scoring of the gymnastics performance with high accuracy, whereby it is possible to improve reliability of the scoring assistance system.

An example of the in-vehicle system recognizes, for example, a position, a type, and the like of the measurement object 100 in front of a vehicle on the basis of an output of the distance measurement apparatus. In this case, the type of the measurement object 100 includes a pedestrian, another vehicle, or the like, and the measurement object 100 is recognized by the computer 4 illustrated in FIG. 2 executing a recognition program, for example. It is sufficient that the computer 4 acquires shape information regarding the measurement object 100 by a well-known method on the basis of 3D data and a distance image from the measurement control unit 5. Since the shape information of the measurement object 100 includes a three-dimensional position of each portion of the measurement object 100 in each frame, it is possible to recognize the position, the type, and the like of the measurement object 100 from the shape information to determine an approaching degree, a level of danger, and the like. Note that, in a case where the distance measurement apparatus is applied to the in-vehicle system, since the distance measurement apparatus itself moves together with the vehicle on which it is mounted, a relative moving speed of the measurement object 100 may be higher. However, according to each of the embodiments described above, it is possible to suppress deterioration in the measurement accuracy of the distance measurement apparatus even for the measurement object 100 having a higher relative moving speed, whereby it is possible to recognize the position, the type, and the like of the measurement object 100 with high accuracy and to improve reliability of the in-vehicle system.

Note that serial numbers assigned to the respective embodiments described above do not represent priority of the preferred embodiments.

While the disclosed distance measurement apparatus, angle-of-view control method, and program have been described above in the embodiments, the present disclosure is not limited to the embodiments described above, and it is needless to say that various modifications, improvements, and substitutions may be made within the scope of the present disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A scanning-type distance measurement apparatus that includes a two-dimensional micro electro mechanical system (MEMS) mirror that reflects a laser beam, comprising:
a memory; and
a processor coupled to the memory and configured to:
drive, on an axis that controls an angle of view out of two axes orthogonal to each other of the two-dimensional MEMS mirror, the axis of the two-dimensional MEMS mirror with a drive signal; and
control a scanning angle range of the laser beam when a drive waveform of the drive signal is offset by an offset amount to shift a center angle of the scanning angle range, on the basis of the offset amount according to a shift direction from the center angle.

2. The distance measurement apparatus according to claim 1, wherein the processor determines the offset amount with reference to a table that stores an offset correction amount with respect to an angle difference between the center angles before and after the shift according to a shift direction, on the basis of the offset correction amount.

3. The distance measurement apparatus according to claim 1, wherein the processor determines the offset amount with reference to a table that stores an offset amount with respect to a shift angle according to a shift direction.

4. The distance measurement apparatus according to claim 1, wherein the processor selects, according to the shift direction, one of a first table that stores an offset amount with respect to a shift angle according to a first shift direction and a second table that stores an offset amount with respect to a shift angle according to a second shift direction, which is an opposite direction to the first shift direction, and determines the offset amount with reference to the selected table.

5. The distance measurement apparatus according to claim 1, wherein
a drive waveform of the drive signal is a non-resonance drive waveform, and
the processor controls the scanning angle range by changing the offset amount in a folding section between folding of the non-resonance drive waveform of the drive signal after end of emission of the laser beam and before start of emission of the laser beam.

6. The distance measurement apparatus according to claim 5, wherein
the shift direction is a direction along a non-resonant driving direction, and
the non-resonance drive waveform of the drive signal is a sawtooth waveform.

7. The distance measurement apparatus according to claim 6, wherein the processor drives the two-dimensional MEMS mirror with a drive signal that has a resonance drive waveform along the other axis out of the two axes.

8. The distance measurement apparatus according to claim 1, further comprising a piezoelectric element that drives and displaces the two-dimensional MEMS mirror along the axis on the basis of the drive signal to control an angle of view of scanning by the laser beam.

9. A angle-of-view control method comprising:
driving, on an axis that controls an angle of view out of two axes orthogonal to each other of a two-dimensional micro electro mechanical system (MEMS) mirror that reflects a laser beam , the axis of the two-dimensional MEMS mirror with a drive signal; and
controlling a scanning angle range of the laser beam when a drive waveform of the drive signal is offset by an offset amount to shift a center angle of the scanning angle range, on the basis of the offset amount according to a shift direction from the center angle.

10. The angle-of-view control method according to claim 9, further comprising:
determining the offset amount with reference to a table that stores an offset correction amount with respect to an angle difference between the center angles before and after the shift according to a shift direction, on the basis of the offset correction amount.

11. The angle-of-view control method according to claim 9, further comprising:
determining the offset amount with reference to a table that stores an offset amount with respect to a shift angle according to a shift direction.

12. The angle-of-view control method according to claim 9, further comprising:
selecting, according to the shift direction, one of a first table that stores an offset amount with respect to a shift angle according to a first shift direction and a second table that stores an offset amount with respect to a shift angle according to a second shift direction, which is an opposite direction to the first shift direction, and
determining the offset amount with reference to the selected table.

13. The angle-of-view control method according to claim 9, wherein
a drive waveform of the drive signal is a non-resonance drive waveform, and
the method further includes controlling the scanning angle range by changing the offset amount in a folding section between folding of the non-resonance drive waveform of the drive signal after end of emission of the laser beam and before start of emission of the laser beam.

14. The angle-of-view control method according to claim 13, wherein
the shift direction is a direction along a non-resonant driving direction, and
the non-resonance drive waveform of the drive signal is a sawtooth waveform.

15. The angle-of-view control method according to a claim 9, wherein the drive signal drives a driving element, which has a hysteresis characteristic and which drives and displaces the two-dimensional MEMS mirror along the axis to control an angle of view of scanning by the laser beam.

16. A non-transitory computer-readable recording medium storing a program causing a computer to execute a processing of:
driving, on an axis that controls an angle of view out of two axes orthogonal to each other of a two-dimensional micro electro mechanical system (MEMS) mirror that reflects a laser beam , the axis of the two-dimensional MEMS mirror with a drive signal; and
controlling a scanning angle range of the laser beam when a drive waveform of the drive signal is offset by an offset amount to shift a center angle of the scanning angle range, on the basis of the offset amount according to a shift direction from the center angle.

17. The non-transitory computer-readable recording medium according to claim 16, further comprising:
determining the offset amount with reference to a table that stores an offset correction amount with respect to an angle difference between the center angles before and after the shift according to a shift direction, on the basis of the offset correction amount.

18. The non-transitory computer-readable recording medium according to claim 16, further comprising:
determining the offset amount with reference to a table that stores an offset amount with respect to a shift angle according to a shift direction.

19. The non-transitory computer-readable recording medium according to claim 16, further comprising:
selecting, according to the shift direction, one of a first table that stores an offset amount with respect to a shift angle according to a first shift direction and a second table that stores an offset amount with respect to a shift angle according to a second shift direction, which is an opposite direction to the first shift direction, and
determining the offset amount with reference to the selected table.

20. The non-transitory computer-readable recording medium according to claim 16, wherein
a drive waveform of the drive signal is a non-resonance drive waveform, and
the method further includes controlling the scanning angle range by changing the offset amount in a folding section between folding of the non-resonance drive waveform of the drive signal after end of emission of the laser beam and before start of emission of the laser beam.
